(19) United States
(12) Patent Application Publication
(10) Pub. No.: US 2006/0081956 A1
(43) Pub. Date: Apr. 20, 2006

(54) Solid-state image sensor

(75) Inventor: Takayuki Kaida, Anpachi-gun (JP)

Correspondence Address: MCDERMOTT WILL & EMERY LLP, 600 13TH STREET, N.W., WASHINGTON, DC, 20005-3096, US

(73) Assignee: SANYO ELECTRIC CO., LTD.

(21) Appl. No.: 11/229,649

(22) Filed: Sep. 20, 2005

(30) Foreign Application Priority Data
Oct. 15, 2004 (JP) JP2004-300846

(51) Int. Cl. H01L 31/00

(52) U.S. Cl. 257/444

(57) ABSTRACT

A solid-state image sensor capable of suppressing deterioration of a transfer efficiency of electrons is provided. The solid-state image sensor comprises a first conductive type first impurity region that can store electrons and holes; a second conductive type second impurity region that is formed so as to have a region where the first and second impurity regions overlap one another; and a transfer electrode that is formed to overlie and extend at least from the first impurity region to the region where the first and second impurity regions overlap one another.

### BACKGROUND OF THE INVENTION

1. Field of the Invention

The present invention relates to a solid-state image sensor, and more particularly to a solid-state image sensor comprising a transfer electrode.

2. Description of the Background Art

Various solid-state image sensors comprising a transfer electrode are known in general. This type of solid-state image sensor is disclosed in Japanese Patent Laying-Open No. 2001-156284, for example.

FIG. 12 is a plan view for illustrating a structure of an imaging part and a storage part of an exemplary conventional solid-state image sensor comprising a transfer electrode. FIG. 13 is a cross-sectional view of the exemplary conventional solid-state image sensor taken along a line 500-500 shown in FIG. 12. With reference to FIG. 12, the exemplary conventional solid-state image sensor comprises an imaging part 401 that performs photoelectric conversion from light incident thereon, and a storage part 402 that stores electrons and holes transferred from the imaging part 401 and transfers the electrons to a horizontal transfer part (not shown). The imaging part 401 has a plurality of pixels 403 that serve to perform photoelectric conversion and are arranged in a matrix shape. The imaging part 401 serves to store the produced electrons and holes and to transfer them to the storage part 402. In the imaging part 401 and the storage part 402, a plurality of transfer electrodes 404 are provided so as to extend along a direction perpendicular to a transfer direction of electrons and holes and to be spaced at a prescribed interval from each other. In addition, three transfer electrodes 404 are provided in one pixel 403. Additionally, three-phase clock signals for transferring electrons and holes are provided to the three transfer electrodes 404 of the imaging part 401 and the storage part 402, respectively. Besides, a p-type channel stop region 405 is provided so as to extend along the transfer direction of electrons and holes between two pixels 403 that are located adjacent to each other along the direction perpendicular to the transfer direction of electrons and holes.

As shown in FIG. 13, a p-type impurity region 407 that has a prescribed depth from the surface of an n-type silicon substrate 406 is formed in the imaging part 401. An n-type impurity region 408 is formed in a predetermined region of the p-type impurity region 407. The n-type impurity region 408 serves to store electrons and holes and to transfer them. The aforementioned plurality of p-type channel stop regions 405 are formed in the n-type impurity region 408. In addition, a p⁺-type hole-ejection region 409 is formed so as to have a p-type overlap region 409a that overlaps the n-type impurity region 408 in the surface in the vicinity of end of the n-type silicon substrate 406. The p-type overlap region 409a has an impurity concentration lower than an impurity concentration of the p⁺-type hole-ejection region 409. Thus, the p-type overlap region 409a has a resistance higher than the p⁺-type hole-ejection region 409. The p⁺-type hole-ejection region 409 is configured such that holes stored in the n-type impurity region 408 under the transfer electrode 404 in OFF state are ejected through the p-type overlap region 409a to the p⁺-type hole-ejection region 409 and the ejected holes are externally ejected through the p⁺-type hole-ejection region 409. An insulating film 410 is formed on the p-type channel stop region 405, the n-type impurity region 408 and a part of the p-type overlap region 409a of the n-type silicon substrate 406. The aforementioned plurality of transfer electrodes 404 are formed on the insulating film 410. The plurality of transfer electrodes 404 are formed to overlie and extend from the n-type impurity region 408 to the part of the p-type overlap region 409a.

The transfer electrode 404 serves to transfer electrons and holes stored in the n-type impurity region 408 by switching the transfer electrode 404 between ON state and OFF state depending on the aforementioned three-phase clock signal. The transfer electrode 404 is configured such that electrons are induced by a positive voltage applied to the transfer electrode 404 and stored in the n-type impurity region 408 under the transfer electrode 404 in ON state when the transfer electrode 404 is turned to ON state by applying a positive voltage clock signal to the transfer electrode 404. The transfer electrode 404 is configured such that holes are induced in the n-type impurity region 408 under the transfer electrode 404 in OFF state, the p-type channel stop region 405 and the part of the p-type overlap region 409a by a negative voltage applied to the transfer electrode 404 when the transfer electrode 404 is turned to OFF state by applying a negative voltage clock signal to the transfer electrode 404. Some of the holes induced in the n-type impurity region 408 under the transfer electrode 404 in OFF state, the p-type channel stop region 405 and the part of the p-type overlap region 409a by a negative voltage applied to the transfer electrode 404 are ejected to the p⁺-type hole ejection region 409 thorough the p-type overlap region 409a, and the rest of holes are stored in the n-type impurity region 408 under the transfer electrode 404 in OFF state.

However, in the exemplary conventional solid-state image sensor shown in FIG. 12, since the transfer electrode 404 is formed to overlie and extend from the n-type impurity region 408 only to the part of the p-type overlap region 409a, holes are not induced in a region of the p-type overlap region 409a that is not overlain by the transfer electrode 404, when the transfer electrode 404 is turned to OFF state. Since a resistance is not reduced in the region of the p-type overlap region 409a that is not overlain by the transfer electrode 404, as a p-type region, there is a disadvantage that holes existing in the n-type impurity region 408 under the transfer electrode 404 in OFF state, the p-type channel stop region 405 and the part of the p-type overlap region 409a are not smoothly ejected to the p⁺-type hole-ejection region 409 through the p-type overlap region 409a. For this reason, since holes stored in the n-type impurity region 408 under the transfer electrode 404 in OFF state are increased, a potential height of the n-type impurity region 408 under the transfer electrode 404 in OFF state is small. As a result, there is a disadvantage that electrons stored in the n-type impurity region 408 under the transfer electrode 404 in ON state adjacent to the transfer electrode 404 in OFF state in the transfer direction flow beyond a potential of the n-type impurity region 408 under the transfer electrode 404 in OFF state into the n-type impurity region 408 under the transfer electrode 404 in ON state on the opposite side of the transfer direction. Consequently, there is a problem that a transfer efficiency of electrons deteriorates.

### SUMMARY OF THE INVENTION

The present invention is aimed at solving the above problems, and it is one object of the present invention to provide a solid-state image sensor capable of suppressing deterioration of a transfer efficiency of electrons.

To achieve the above object, a solid-state image sensor according to a first aspect of the present invention comprises a first conductive type first impurity region that is formed in a main surface of a semiconductor substrate and can store electrons and holes; a second conductive type second impurity region that is formed in the main surface of the semiconductor substrate so as to have a region where the first and second impurity regions overlap one another; and a transfer electrode that is formed to overlie and extend at least from the first impurity region of the semiconductor substrate to the region where the first and second impurity regions overlap one another.

In the solid-state image sensor according to the first aspect, as mentioned above, the transfer electrode that is formed to overlie and extend at least from the first impurity region of the semiconductor substrate to the region where the first and second impurity regions overlap one another is provided, thus, when the transfer electrode is turned to OFF state (negative potential), holes can be induced in the whole region where the first and second impurity regions overlap one another under the transfer electrode. Accordingly, it is possible to reduce a resistance of the whole region where the first and second impurity regions overlap one another under the transfer electrode in OFF state. Therefore, since holes existing under the transfer electrode in OFF state can be smoothly ejected toward the second impurity region side through the region where the first and second impurity regions overlap one another, it is possible to suppress increase of holes stored in the first impurity region under the transfer electrode in OFF state. Consequently, since reduction of a potential height of the first impurity region under the transfer electrode in OFF state due to increase of holes stored in the first impurity region under the transfer electrode in OFF state can be suppressed, it is possible to suppress that electrons stored in the first impurity region under the transfer electrode in ON state adjacent to the transfer electrode in OFF state in the transfer direction flow beyond a potential of the first impurity region under the transfer electrode in OFF state into the first impurity region under the transfer electrode in ON state on the opposite side of the transfer direction. As a result, it is possible to suppress deterioration of a transfer efficiency of electrons.

In the aforementioned solid-state image sensor according to the first aspect, preferably, the transfer electrode is formed to overlie and extend at least from the first impurity region of the semiconductor substrate to an end on the second impurity region side of the region where the first and second impurity regions overlap one another. In this constitution, since when the transfer electrode is turned to OFF state (negative potential) holes can be easily induced in the whole region where the first and second impurity regions overlap one another under the transfer electrode, it is possible to easily eject holes existing under the transfer electrode in OFF state toward the second impurity region side through the region where the first and second impurity regions overlap one another under the transfer electrode in OFF state.

In this case, it is preferable that the transfer electrode is formed to overlie and extend from the first impurity region of the semiconductor substrate not only to the region where the first and second impurity regions overlap one another but also to a part of a region of the second impurity region where the first and second impurity regions do not overlap one another. In this constitution, when the transfer electrode is turned to OFF state (negative potential), more holes tend to be induced in an edge on the second impurity region side of the region where the first and second impurity regions overlap one another as compared with the case where the transfer electrode extends only to a position directly above the edge on the second impurity region side of the region where the first and second impurity regions overlap one another. Accordingly, since turning the transfer electrode to OFF state can further ensure induction of holes in the edge on the second impurity region side of the region where the first and second impurity regions overlap one another under the transfer electrode in OFF state, it is possible to further ensure reduction of a resistance of the whole region where the first and second impurity regions overlap one another under the transfer electrode in OFF state.

In the aforementioned solid-state image sensor according to the first aspect, preferably, the sensor further comprises an imaging part and a storage part each of which includes the first and second impurity regions and the transfer electrode, and the transfer electrode of each of the imaging part and the storage part is formed to overlie and extend at least from the first impurity region of the semiconductor substrate to the region where the first and second impurity regions overlap one another. In this constitution, in each of the imaging part and the storage part, since when the transfer electrode is turned to OFF state (negative potential) holes can be easily induced in the whole region where the first and second impurity regions overlap one another under the transfer electrode, it is possible to easily eject holes existing under the transfer electrode in OFF state toward the second impurity region side through the region where the first and second impurity regions overlap one another under the transfer electrode in OFF state.

In the aforementioned solid-state image sensor according to the first aspect, preferably, the transfer electrode is formed to overlie and extend at least from the first impurity region of the semiconductor substrate to the region where the first and second impurity regions overlap one another so as to interpose a fist insulating film between the transfer electrode and the main surface of the semiconductor substrate. In this constitution, since when the transfer electrode is turned to OFF state (negative potential) the transfer electrode can easily apply a negative electric filed to the whole region where the first and second impurity regions overlap one another under the transfer electrode through the first insulating film, it is possible to easily induce holes in the whole region where the first and second impurity regions overlap one another under the transfer electrode.

In the aforementioned solid-state image sensor according to the first aspect, preferably, the region where the first and second impurity regions overlap one another has a second conductivity, and an impurity concentration lower than the second conductive type second impurity region. As mentioned above, since the region where the first and second impurity regions overlap one another has an impurity concentration lower than the second impurity region, in the case where the region where the first and second impurity regions overlap one another has a resistance higher than the second impurity region, providing the transfer electrode according to the present invention that is formed to overlie and extend at least from the first impurity region to the region where the first and second impurity regions overlap one another can reduce a resistance in the whole region where the first and second impurity regions overlap one another under the transfer electrode in OFF state. As a result, also in the case where the region where the first and second impurity regions overlap one another has a second conductivity, and has an impurity concentration lower than the second impurity region, it is possible to easily eject holes stored in the first impurity region under the transfer electrode in OFF state toward the second impurity region side through the region where the first and second impurity regions overlap one another.

In the aforementioned solid-state image sensor according to the first aspect, preferably, a plurality of the transfer electrodes are formed to extend along a direction that intersects a transfer direction of the electrons in the first impurity region and to be arranged adjacent to each other in the transfer direction of the electrons, and serve to transfer the electrons and the holes in the first impurity region by switching the transfer electrodes between ON state and OFF state, and the electrons are stored in the first impurity region under the transfer electrode in ON state, and the holes are stored in the first impurity region under the transfer electrode in OFF state, and the holes stored in the first impurity region under the transfer electrode in the OFF state are ejected toward the second impurity region side through the region where the first and second impurity regions overlap one another. In this constitution, turning the transfer electrode formed to overlie and extend at least from the first impurity region of the semiconductor substrate to the region where the first and second impurity regions overlap one another to OFF state can easily eject the holes stored in the first impurity region under the transfer electrode in OFF state toward the second impurity region side through the region where the first and second impurity regions overlap one another.

In this case, the transfer electrode may be turned to ON state by applying a positive voltage clock signal to the transfer electrode, and be turned to OFF state by applying a negative voltage clock signal to the transfer electrode. In this constitution, electrons can be easily stored in the first impurity region under the transfer electrode in ON state, and holes can be easily stored in the first impurity region under the transfer electrode in OFF state.

In the aforementioned solid-state image sensor according to the first aspect, preferably, the sensor further comprises an imaging part and a storage part each of which includes the first and second impurity regions and the transfer electrode, and a transfer rate of the hole in the first impurity region of the storage part is smaller than a transfer rate of the hole in the first impurity region of the imaging part, and at least the transfer electrode in the vicinity of a boundary between the imaging part and the storage part is formed to overlie and extend at least from the first impurity region of the semiconductor substrate to the region where the first and second impurity regions overlap one another. In the case where a transfer rate of the hole in the first impurity region of the storage part is smaller than a transfer rate of the hole in the first impurity region of the imaging part as mentioned above, holes stored in the first impurity region under the transfer electrode in OFF state tend to increase in a region in the vicinity of the boundary between the imaging part and the storage part. Even in this case, since the transfer electrode in the vicinity of the boundary between the imaging part and the storage part is formed to overlie and extend at least from the first impurity region to the region where the first and second impurity regions overlap one another, it is possible to reduce a resistance of the whole region where the first and second impurity regions overlap one another under the transfer electrode in OFF state. Consequently, it is possible to effectively eject the holes that increase and are stored in the first impurity region under the transfer electrode in OFF state in the region in the vicinity of the boundary between the imaging part and the storage part toward the second impurity region through the region where the first and second impurity regions.

In the aforementioned solid-state image sensor in which a transfer rate of the hole in the first impurity region of the storage part is smaller than a transfer rate of the hole in the first impurity region of the imaging part, a first clock signal may be provided to the transfer electrode of the imaging part, and a second clock signal with a rate lower than the first clock signal may be provided to the transfer electrode of the storage part. In this constitution, a transfer rate of the hole in the first impurity region of the storage part can be easily smaller than a transfer rate of the hole in the first impurity region of the imaging part.

In the aforementioned solid-state image sensor in which a transfer rate of the hole in the first impurity region of the storage part is smaller than a transfer rate of the hole in the first impurity region of the imaging part, at least the transfer electrode in the vicinity of the boundary between the imaging part and the storage part is formed to overlie and extend at least from the first impurity region of the semiconductor substrate to an end on the second impurity region side of the region where the first and second impurity regions overlap one another. In this constitution, since, when the transfer electrode is turned to OFF state (negative potential), holes can be easily induced in the whole region where the first and second impurity regions overlap one another under at least the transfer electrode in the vicinity of the boundary between the imaging part and the storage part and thus can reduce a resistance, it is possible to effectively eject holes that increase and are stored in the first impurity region under the transfer electrode in OFF state in the vicinity of the boundary between the imaging part and the storage part toward the second impurity region through the region where the first and second impurity regions overlap one another.

In this case, preferably, at least the transfer electrode in the vicinity of the boundary between the imaging part and the storage part is formed to overlie and extend from the first impurity region of the semiconductor substrate not only to the region where the first and second impurity regions overlap one another but also to a part of a region of the second impurity region where the first and second impurity regions do not overlap one another. In this constitution, when the transfer electrode in the vicinity of the boundary between the imaging part and the storage part is turned to OFF state (negative potential), more holes can tend to be induced in an edge on the second impurity region side of the region where the first and second impurity regions overlap one another as compared with the case where the transfer electrode in the vicinity of the boundary between the imaging part and the storage part extends only to a position directly above the edge on the second impurity region side of the region where the first and second impurity regions overlap one another.

In the aforementioned solid-state image sensor according to the first aspect, the second impurity region, and the region where the first and second impurity regions overlap one another may have a depth smaller than a depth of the first impurity region.

In the aforementioned solid-state image sensor according to the first aspect, preferably, the sensor further comprises a plurality of second conductive type channel stop regions that are formed in the surface of the first impurity region to be spaced at a prescribed interval from each other and to extend in the transfer direction of the electrons and holes in order to make a separation into pixels. In this constitution, the channel stop regions can make a separation into pixels adjacent to each other in a direction that intersects a transfer direction of charge, and the transfer electrode that overlies and extends the region where the first and second impurity regions overlap one another can accelerate ejection of holes that is induced in the channel stop region under the transfer electrode in OFF state toward the second impurity region side through the region where the first and second impurity regions overlap one another under the transfer electrode in OFF state.

In the aforementioned solid-state image sensor comprising the second conductive type channel stop regions, the channel stop region, the second impurity region, and the region where the first and second impurity regions overlap one another may have a depth smaller than a depth of the first impurity region. Furthermore, in the aforementioned solid-state image sensor comprising the second conductive type channel stop regions, the second conductive type channel stop region may have an impurity concentration lower than the second conductive type second impurity region.

In the aforementioned solid-state image sensor according to the first aspect, a plurality of the transfer electrodes may be formed to be spaced at a prescribed interval from each other in a transfer direction of the electrons and not to overlap one another, and each of the plurality of the transfer electrodes may be formed to overlie and extend at least from the first impurity region of the semiconductor substrate to the region where the first and second impurity regions overlap one another. In a structure where the transfer electrodes are formed to be spaced at a prescribed interval from each other in the transfer direction of the electrons and not to overlap one another as mentioned above, in the case where each of the plurality of the transfer electrodes is formed to overlie and extend at least from the first impurity region of the semiconductor substrate to the region where the first and second impurity regions overlap one another, when the transfer electrode is turned to OFF state (negative potential), holes can be also induced in the whole region where the first and second impurity regions overlap one another under the transfer electrode. Accordingly, it is possible to easily reduce a resistance of the whole region where the first and second impurity regions overlap one another under the transfer electrode in OFF state.

In the aforementioned solid-state image sensor according to the first aspect, a plurality of the transfer electrodes may be formed to be arranged adjacent to each other so as to overlap one another in a transfer direction of the electrons to interpose a second insulating film between the transfer electrodes, and each of the plurality of the transfer electrodes may be formed to overlie and extend at least from the first impurity region of the semiconductor substrate to the region where the first and second impurity regions overlap one another. In a structure where the transfer electrodes are formed to be arranged adjacent to each other so as to overlap one another in the transfer direction of the electrons to interpose the second insulating film between the transfer electrodes as mentioned above, in the case where each of the plurality of the transfer electrodes is formed to overlie and extend at least from the first impurity region of the semiconductor substrate to the region where the first and second impurity regions overlap one another, when the transfer electrode is turned to OFF state (negative potential), holes can be also induced in the whole region where the first and second impurity regions overlap one another under the transfer electrode. Accordingly, it is possible to easily reduce a resistance of the whole region where the first and second impurity regions overlap one another under the transfer electrode in OFF state.

In the aforementioned solid-state image sensor according to the first aspect, preferably, the semiconductor substrate has a first conductivity, and the sensor further comprises a second conductive type third impurity region formed in the main surface of the first conductive type semiconductor substrate, and the first conductive type first impurity region is formed in a main surface of the second conductive type third impurity region. In this constitution, it is possible to pull out electrons that overflow from a potential well of the first impurity region storing electrons through the second conductive type third impurity region toward the first conductive type semiconductor substrate side.

A solid-state image sensor according to a second aspect of the present invention comprises an n-type first impurity region that is formed in a main surface of a semiconductor substrate and can store electrons and holes; a p-type second impurity region that is formed in the main surface of the semiconductor substrate so as to have a region where the first and second impurity regions overlap one another; and a transfer electrode that is formed to overlie and extend from the first impurity region of the semiconductor substrate not only to the region where the first and second impurity regions overlap one another but also to a part of a region of the second impurity region where the first and second impurity regions do not overlap one another.

In the solid-state image sensor according to the second aspect, since the transfer electrode is formed to overlie and extend from the first impurity region of the semiconductor substrate not only to the region where the n-type first impurity region and the p-type second impurity region overlap one another but also to a part of the region of the second impurity region where the first and second impurity regions do not overlap one another as mentioned above, when the transfer electrode is turned to OFF state (negative potential), more holes tend to be induced in an edge on the p-type second impurity region side of the region where the n-type first impurity region and the p-type second impurity region overlap one another as compared with the case where the transfer electrode extends only to a position directly above the edge on the p-type second impurity region side of the region where the n-type first impurity region and the p-type second impurity region overlap one another. Accordingly, since turning the transfer electrode to OFF state can further ensure induction of holes in the edge on the p-type second impurity region side of the region where the n-type first impurity region and the p-type second impurity region overlap one another under the transfer electrode in OFF state, it is possible to further ensure reduction of a resistance of the whole region where the n-type first impurity region and the p-type second impurity region overlap one another under the transfer electrode in OFF state. Therefore, since holes existing under the transfer electrode in OFF state can be more smoothly ejected toward the p-type second impurity region side through the region where the n-type first impurity region and the p-type second impurity region overlap one another, it is possible to further suppress increase of holes stored in the n-type first impurity region under the transfer electrode in OFF state. Consequently, since reduction of a potential height of the n-type first impurity region under the transfer electrode in OFF state due to increase of holes stored in the n-type first impurity region under the transfer electrode in OFF state can be further suppressed, it is possible to further suppress that electrons stored in the n-type first impurity region under the transfer electrode in ON state adjacent to the transfer electrode in OFF state in the transfer direction flow beyond a potential of the n-type first impurity region under the transfer electrode in OFF state into the n-type first impurity region under the transfer electrode in ON state on the opposite side of the transfer direction. As a result, it is possible to suppress deterioration of a transfer efficiency of electrons.

### BRIEF DESCRIPTION OF THE DRAWINGS

FIG. 1 is a view schematically showing the whole constitution of a solid-state image sensor according to one embodiment of the present invention;

FIG. 2 is a plan view for illustrating a structure of an imaging part and a storage part of the solid-state image sensor according to the one embodiment shown in FIG. 1;

FIG. 3 is a cross-sectional view of the solid-state image sensor according to the one embodiment taken along a line 100-100 shown in FIG. 2;

FIG. 4 is a cross-sectional view of the solid-state image sensor according to the one embodiment taken along a line 150-150 shown in FIG. 2;

FIG. 5 is a cross-sectional view for illustrating a manufacturing process of the solid-state image sensor according to the one embodiment of the present invention;

FIG. 6 is a cross-sectional view for illustrating a manufacturing process of the solid-state image sensor according to the one embodiment of the present invention;

FIG. 7 is a cross-sectional view for illustrating a manufacturing process of the solid-state image sensor according to the one embodiment of the present invention;

FIG. 8 is a plan view for illustrating a structure of an imaging part and a storage part of a solid-state image sensor according to a first modified example of the one embodiment;

FIG. 9 is a cross-sectional view of the solid-state image sensor according to the first modified example taken along a line 250-250 shown in FIG. 8;

FIG. 10 is a plan view for illustrating a structure of an imaging part and a storage part of a solid-state image sensor according to a second modified example of the one embodiment;

FIG. 11 is a cross-sectional view of the solid-state image sensor according to the second modified example taken along a line 300-300 shown in FIG. 10;

FIG. 12 is a plan view for illustrating a structure of an imaging part and a storage part of an exemplary conventional solid-state image sensor comprising the transfer electrode; and

FIG. 13 is a cross-sectional view of the exemplary conventional solid-state image sensor taken along a line 500-500 shown in FIG. 12.

### DESCRIPTION OF THE PREFERRED EMBODIMENT

An embodiment of the present invention is now described with reference to the drawings.

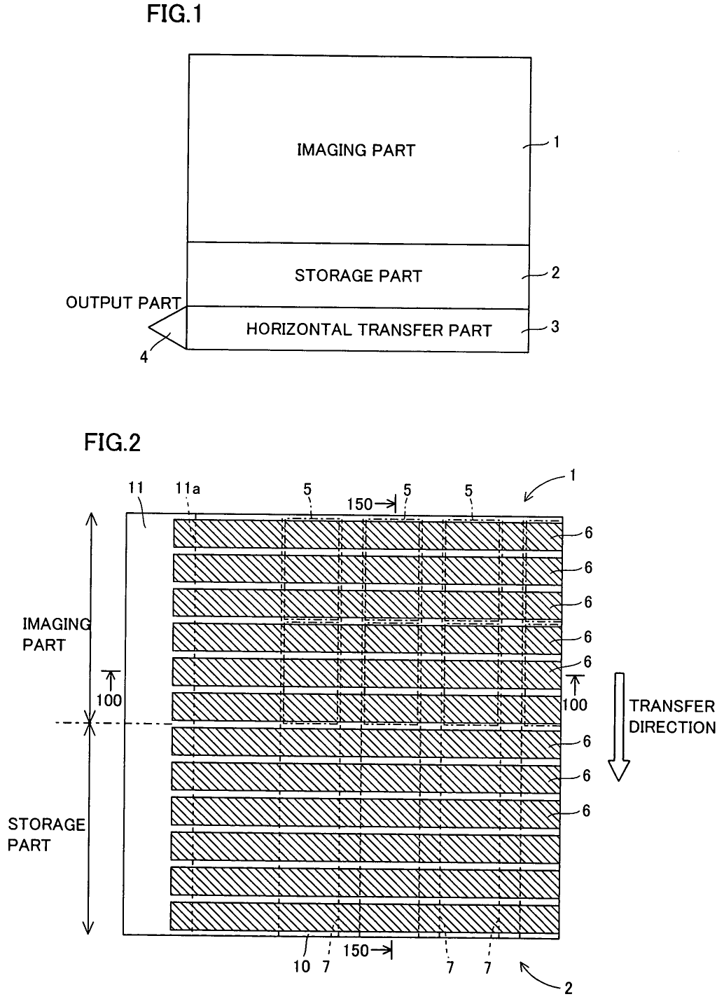

With reference to FIGS. 1 to 4, in this embodiment, an exemplary frame transfer type solid-state image sensor to which the present invention is applied is described.

The frame transfer type solid-state image sensor according to this embodiment comprises an imaging part 1, a storage part 2, a horizontal transfer part 3, and an output part 4, as shown in FIG. 1. The imaging part 1 is provided to perform photoelectric conversion from light incident thereon. The imaging part 1 has a plurality of pixels 5 that serve to perform photoelectric conversion and are arranged in a matrix shape, as shown in FIG. 2. The imaging part 1 serves to store the produced electrons and holes and to transfer the electrons and holes to the storage part 2. Some of holes stored in the imaging part 1 are externally ejected through a later-described p⁺-type hole-ejection region 11 of the imaging part 1. The storage part 2 serves to store and transfer electrons and holes transferred from the imaging part 1. The horizontal transfer part 3 serves to sequentially transfer the electrons transferred from the storage part 2 to the output part 4. Some of holes stored in the storage part 2 are not transferred to the horizontal transfer part 3, but are externally ejected through the later-described p⁺-type hole-ejection region 11 of the storage part 2. The output part 4 serves to provide the electrons transferred from the horizontal transfer part 3 as an electrical signal.

In the imaging part 1 and the storage part 2, as shown in FIG. 2, a plurality of transfer electrodes 6 consisting of polycrystalline silicon are provided so as to extend along a direction perpendicular to a transfer direction of electrons and holes and to be spaced at a prescribed interval from each other. In addition, three transfer electrodes 6 are provided in each one pixel 5. Additionally, three-phase clock signals for transferring electrons and holes are provided to the three transfer electrodes 6 of the imaging part 1 and the storage part 2, respectively. A three-phase clock signal with a rate lower than three-phase clock signal provided to the transfer electrode 6 of the imaging part 1 is provided to the transfer electrode 6 of the storage part 2. Additionally, a p-type channel stop region 7 is provided so as to extend along a transfer direction of electrons and holes between two pixels 5 that are located adjacent to each other along a direction perpendicular to the transfer direction of electrons.

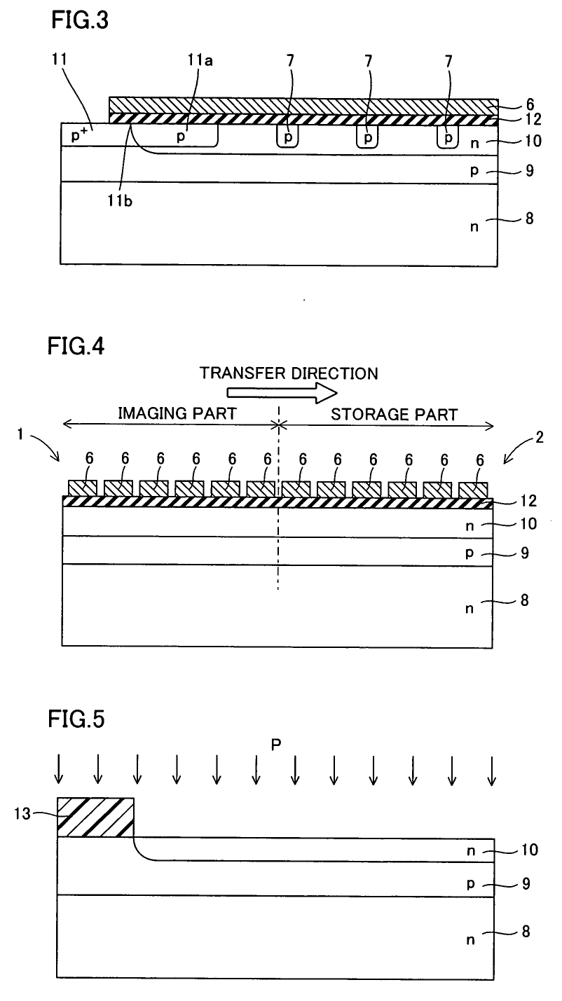

As shown in FIGS. 3 and 4, a p-type impurity region 9 that has a prescribed depth from the surface of an n-type silicon substrate 8 is formed in the imaging part 1 and the storage part 2. The n-type silicon substrate 8 is an example of a “semiconductor substrate” in the present invention. In addition, an n-type impurity region 10 that has a depth of about 0.6 μm from the surface of the n-type silicon substrate 8 and an n-type impurity concentration of about 2×10¹⁶ cm⁻³ is formed in a prescribed region in the p-type impurity region 9. The n-type impurity region 10 is an example of a “first impurity region” in the present invention. The n-type impurity region 10 serves to store and transfer electrons and holes. The n-type impurity region 10, the p-type impurity region 9, and the n-type silicon substrate 8 compose a vertical overflow drain structure that carries off electrons overflowing from a potential well of the n-type impurity region 10 storing electrons toward the n-type silicon substrate 8 side. As shown in FIG. 3, the aforementioned plurality of p-type channel stop regions 7 are formed in the n-type impurity region 10. The p-type channel stop region 7 has a depth of about 0.5 μm from the surface of the n-type silicon substrate 8 and a p-type impurity concentration of about 3×10¹⁶ cm⁻³.

In addition, a p⁺-type hole-ejection region 11 is formed so as to have a p-type overlap region 11a that overlaps the n-type impurity region 10 in the surface at an end of the n-type silicon substrate 8. The p⁺-type hole-ejection region 11 is an example of a “second impurity region” in the present invention. The p⁺-type hole-ejection region 11 has a depth of about 0.5 μm from the surface of the n-type silicon substrate 8 and a p-type impurity concentration of about 5×10¹⁶ cm⁻³. The p-type overlap region 11a has a depth of about 0.5 μm from the surface of the n-type silicon substrate 8 and a p-type impurity concentration of about 3×10¹⁶ cm⁻³. That is, the p-type overlap region 11a has a p-type impurity concentration (about 3×10¹⁶ cm⁻³) lower than the p-type impurity concentration (about 5×10¹⁶ cm⁻³) of the p⁺-type hole-ejection region 11. Thus, the p-type overlap region 11a has a resistance higher than the p⁺-type hole-ejection region 11. The p⁺-type hole-ejection region 11 is configured such that holes stored in the n-type impurity region 10 under the transfer electrode 6 in OFF state are ejected through the p-type overlap region 11a to the p⁺-type hole-ejection region 11 and the ejected holes are externally ejected through the p⁺-type hole-ejection region 11. An insulating film 12 consisting of SiO₂ is formed on the p-type channel stop region 7, the n-type impurity region 10, the p-type overlap region 11a and a prescribed region of the p⁺-type hole-ejection region 11 of the n-type silicon substrate 8. The aforementioned plurality of transfer electrodes 6 are formed on the insulating film 12.

The transfer electrode 6 serves to transfer electrons and holes stored in the n-type impurity region 10 by switching the transfer electrode 6 between ON state and OFF state depending on the aforementioned three-phase clock signal. The transfer electrode 6 is configured such that electrons are induced by a positive voltage applied to the transfer electrode 6 and stored in the n-type impurity region 10 under the transfer electrode 6 in ON state when the transfer electrode 6 is turned to ON state by applying a positive voltage clock signal to the transfer electrode 6. The transfer electrode 6 is configured such that holes are induced in the n-type impurity region 10 under the transfer electrode 6 in OFF state, the p-type channel stop region 7 and the p-type overlap region 11a by a negative voltage applied to the transfer electrode 6 when the transfer electrode 6 is turned to OFF state by applying a negative voltage clock signal to the transfer electrode 6. Some of the holes induced in the n-type impurity region 10 under the transfer electrode 6 in OFF state, the p-type channel stop region 7 and the p-type overlap region 11a by a negative voltage applied to the transfer electrode 6 are ejected toward the p⁺-type hole ejection region 11 side, and the rest of holes are stored in the n-type impurity region 10 under the transfer electrode 6 in OFF state.

In this embodiment, as shown in FIGS. 2 and 3, the plurality of transfer electrodes 6 are formed to overlie and extend from the n-type impurity region 10 of the n-type silicon substrate 8 to the whole region of the p-type overlap region 11a. Accordingly, when the transfer electrode 6 is turned to OFF state (negative potential), holes are induced in the whole region from the n-type impurity region 10 to an edge 11b on the p⁺-type hole ejection region 11 side of the p-type overlap region 11a under the transfer electrode 6 in OFF state. Therefore, a resistance over the whole region of the p-type overlap region 11a under the transfer electrode 6 in OFF state is reduced. In addition, since the transfer electrode 6 is formed to extend beyond the edge 11b on the p⁺-type hole ejection region 11 side of the p-type overlap region 11a to a part of the p⁺-type hole ejection region 11, when the transfer electrode 6 is turned to OFF state (negative potential) more holes tend to be induced at the edge 11b on the p⁺-type hole ejection region 11 side of the p-type overlap region 11a as compared with the case where the transfer electrode 6 extends only to a position directly above the edge 11b on the p⁺-type hole ejection region 11 side of the p-type overlap region 11a. Additionally, in this embodiment, a clock signal with a low rate as compared with a clock signal provided to the transfer electrode 6 of the imaging part 1 is provided to the transfer electrode 6 of the storage part 2, thus, a transfer rate of hole in the n-type impurity region 10 of the storage part 2 is smaller than a transfer rate of hole in the n-type impurity region 10 of the imaging part 1. Therefore, holes that are stored in the n-type impurity region 10 under the transfer electrode 6 in OFF state tend to increase in a region in the vicinity of a boundary between the imaging part 1 and the storage part 2.

In this embodiment, since the transfer electrode 6 is formed to overlie and extend from the n-type impurity region 10 to the whole region of the p-type overlap region 11a as mentioned above, when the transfer electrode 6 is turned to OFF state (negative potential), holes can be induced in the whole region of the p-type overlap region 11a under the transfer electrode 6. Accordingly, it is possible to reduce a resistance in the whole region of the p-type overlap region 11a under the transfer electrode 6 in OFF state. Thus, since holes stored in the n-type impurity region 10 under the transfer electrode 6 in OFF state can be smoothly ejected toward the p⁺-type hole-ejection region 11 side through the p-type overlap region 11a under the transfer electrode 6 in OFF state, it is possible to suppress increase of holes stored in the n-type impurity region 10 under the transfer electrode 6 in OFF state. Consequently, since reduction of a potential height of the n-type impurity region 10 under the transfer electrode 6 in OFF state due to increase of holes stored in the n-type impurity region 10 under the transfer electrode 6 in OFF state can be suppressed, it is possible to suppress that electrons stored in the n-type impurity region 10 under the transfer electrode 6 in ON state adjacent to the transfer electrode 6 in OFF state in the transfer direction flow beyond a potential of the n-type impurity region 10 under the transfer electrode 6 in OFF state into the n-type impurity region 10 under the transfer electrode 6 in ON state on the opposite side of the transfer direction. As a result, it is possible to suppress deterioration of a transfer efficiency of electrons.

In this embodiment, since the transfer electrode 6 is formed to extend from the n-type impurity region 10 beyond the edge 11b on the p⁺-type hole ejection region 11 side of the p-type overlap region 11a to a part of the p⁺-type hole ejection region 11, when the transfer electrode 6 is turned to OFF state (negative potential), more holes tend to be induced at the edge 11b on the p⁺-type hole ejection region 11 side of the p-type overlap region 11a as compared with the case where the transfer electrode 6 extends only to a position directly above the edge 11b on the p⁺-type hole ejection region 11 side of the p-type overlap region 11a. Accordingly, since turning the transfer electrode 6 to OFF state can further ensure induction of holes in the edge 11b on the p⁺-type hole ejection region 11 side of the p-type overlap region 11a under the transfer electrode 6 in OFF state, it is possible to further ensure reduction of a resistance of the whole region in the p-type overlap region 11a under the transfer electrode 6 in OFF state.

In this embodiment, since a transfer rate of hole in the n-type impurity region 10 of the storage part 2 is smaller than a transfer rate of hole in the n-type impurity region 10 of the imaging part 1, even in the case where holes that are stored in the n-type impurity region 10 under the transfer electrode 6 in OFF state tend to increase in a region in the vicinity of the boundary between the imaging part 1 and the storage part 2, forming the transfer electrode 6 to overlie and extend from the n-type impurity region 10 to the p-type overlap region 11a can reduce a resistance of the whole region in the p-type overlap region 11a under the transfer electrode 6 in OFF state. Therefore, it is possible to effectively eject the holes that increase and are stored in the n-type impurity region 10 under the transfer electrode 6 in OFF state in the region in the vicinity of the boundary between the imaging part 1 and the storage part 2 toward the p⁺-type hole ejection region 11 through the p-type overlap region 11a.

A manufacturing process of the transfer type solid-state image sensor according to one embodiment of the present invention is described with reference to FIGS. 2 to 7.

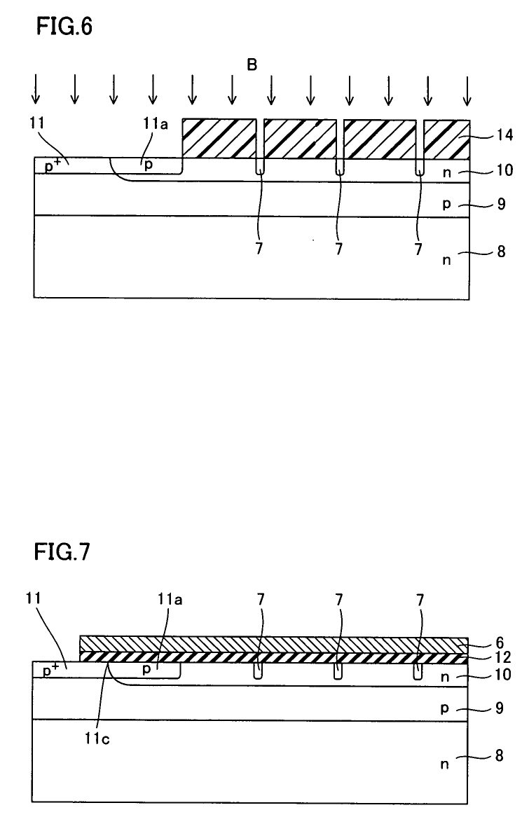

First, as shown in FIG. 5, the p-type impurity region 9 that has a prescribed depth from the surface of the n-type silicon substrate 8 is formed. After that, a resist film 13 is formed to cover a region except a region where the n-type impurity region 10 is formed by photolithography. Subsequently, the resist film 13 serves as a mask, and P (phosphorus) is introduced to the n-type silicone substrate 8 by ion implantation under conditions of implantation energy of about 150 keV, and a dose of about 5×10¹¹ cm⁻². Thus, the n-type impurity region 10 that has a depth of about 0.36 μm from the surface of the n-type silicon substrate 8 is formed. After that, the resist film 13 is removed. Then, as shown in FIG. 6, a resist film 14 is formed to cover a region except regions where the p-type channel stop regions 7, the p-type overlap region 11a and the p⁺-type hole-ejection region 11 are formed by photolithography. Subsequently, the resist film 14 serves as a mask, and B (boron) is introduced to the n-type silicone substrate 8 by ion implantation under conditions of implantation energy of about 50 keV, and a dose of about 2×10¹² cm⁻². Thus, the plurality of p-type channel stop regions 7 that have a depth of about 0.3 μm from the surface of the n-type silicon substrate 8 are formed to be spaced at a prescribed interval from each other. In addition, the p⁺-type hole-ejection region 11 that has a depth of about 0.3 μm from the surface of the n-type silicon substrate 8 is formed so as to have the p-type overlap region 11a that overlaps the n-type impurity region 10. After that, the resist film 14 is removed. Next, as shown in FIG. 7, the insulating film 12 consisting of SiO₂ is formed to cover a region except a prescribed region in an end of the semiconductor substrate 8. After a polycrystalline silicon film (not shown) is deposited on the insulating film 12, patterning is performed on the polycrystalline silicon film by employing photolithography and etching, thus, the plurality of transfer electrodes 6 are formed to be spaced at a prescribed interval from each other.

In this process, in this embodiment, patterning is performed such that the plurality of transfer electrodes 6 overlie and extend from the n-type impurity region 10 of the n-type silicon substrate 8 not only to the p-type overlap region 11a but also to a prescribed region of the p⁺-type hole-ejection region 11. In addition, in order for the p-type overlap region 11a that is not overlain by the transfer electrode 6 not to exist even in the case where the p-type overlap region 11a spreads toward the p⁺-type hole-ejection region 11 side due to thermal diffusion of P (phosphorus) in the n-type impurity region 10 by later-described heat treatment, the transfer electrode 6 is formed to extend about 0.24 μm or more from an edge 11c of the p-type overlap region 11a toward the p⁺-type hole-ejection region 11 side.

Finally, heat treatment is performed at about 950° C. for about one hour. Thus, P (phosphorus) in the n-type impurity region 10, B (boron) in the p-type channel stop region 7 and the p⁺-type hole-ejection region 11 thermally and isotropically diffuse. As a result, as shown in FIG. 3, the n-type impurity region 10 that has a depth of about 0.6 μm from the surface of the n-type silicon substrate 8 and an n-type impurity concentration of about 2×10¹⁶ cm⁻³ is formed. In addition, the plurality of p-type channel stop regions 7 that are spaced at a prescribed interval from each other and have a depth of about 0.5 μm from the surface of the n-type silicon substrate 8 and a p-type impurity concentration of about 3×10¹⁶ cm⁻³ is formed. Additionally, the p⁺-type hole-ejection region 11 that has a depth of about 0.5 μm from the surface of the n-type silicon substrate 8 and a p-type impurity concentration of about 5×10¹⁶ cm⁻³ is formed. Moreover, the p-type overlap region 11a that has a depth of about 0.5 μm from the surface of the n-type silicon substrate 8 and a p-type impurity concentration of about 3×10¹⁶ cm⁻³ is formed. In this case, the p-type overlap region 11a spreads toward the p⁺-type hole-ejection region 11 side, thus, the new edge 11b (see FIG. 3) of the p-type overlap region 11a is formed at a location that is shifted about 0.24 μm from the edge 11c of the p-type overlap region 11a shown in FIG. 7 toward the p⁺-type hole-ejection region 11 side. In this case, an end of the transfer electrode 6 is located on the p⁺-type hole-ejection region 11 side relative to the edge 11b of the p-type overlap region 11a. As mentioned above, the frame transfer type solid-state image sensor according to this embodiment shown in FIGS. 2 to 4 is formed.

It should be appreciated, however, that the embodiment described above is illustrative, and the invention is not specifically limited to description above. The invention is defined not by the foregoing description of the embodiment, but by the appended claims, their equivalents, and various modifications that can be made without departing from the scope of the invention as defined in the appended claims.

In the foregoing embodiment, the case where the present invention is applied to a frame transfer type solid-state image sensor is described, however, the present invention is not limited to this case. For example, the present invention can be applied to a solid-state image sensor other than a frame transfer type solid-state image sensor.

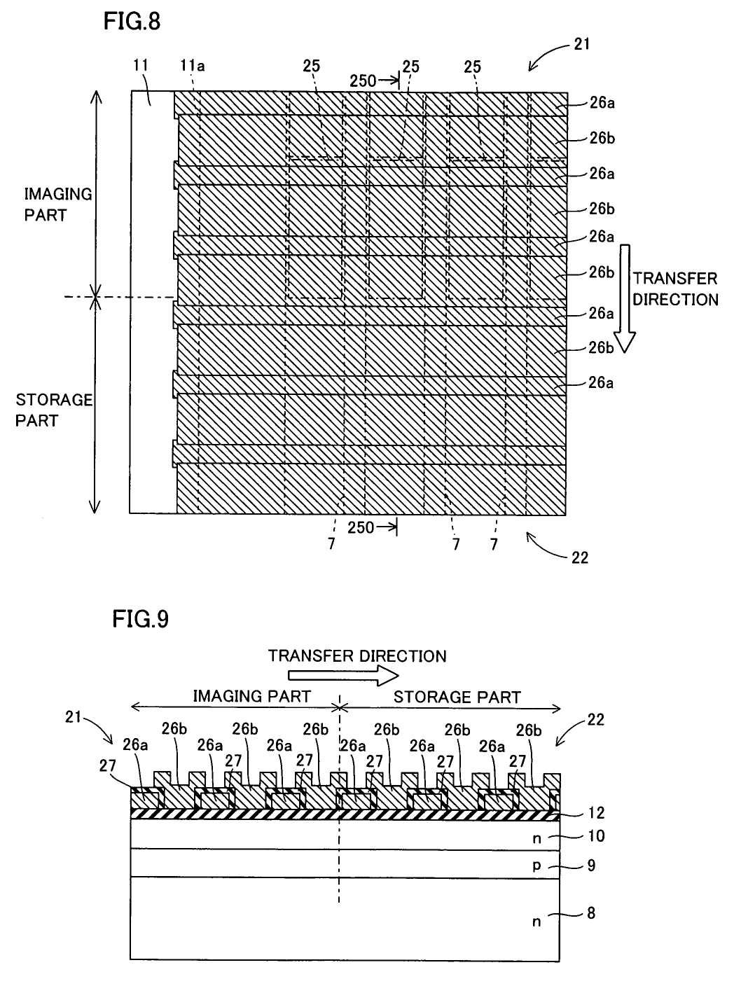

In addition, in the foregoing embodiment, the plurality of transfer electrode are provided to be spaced at a prescribed interval from each other and not to overlap one another, however, the present invention is not limited to this constitution. Two transfer electrodes adjacent to each other may be provided to partially overlap one another. FIG. 8 shows a structure of an imaging part and a storage part of a solid-state image sensor according to a first modified example of the one embodiment, in which two transfer electrodes adjacent to each other are provided to partially overlap one another. FIG. 9 shows a cross-sectional view of the solid-state image sensor according to the first modified example taken along a line 250-250 shown in FIG. 8. With reference to FIGS. 8 and 9, in the solid-state image sensor according to the first modified example, two transfer electrodes 26a and 26b adjacent to each other in a transfer direction of electrons and holes are configured such that their ends partially overlap one another to interpose an insulating film 27 between them in the imaging part 1 and the storage part 2 dissimilarly to the solid-state image sensor according the foregoing embodiment. Two transfer electrodes 26a and two transfer electrodes 26b are provided in one pixel 25. In other words, four transfer electrodes 26a and 26b are provided in one pixel 25. Four-phase clock signals are provided to the four transfer electrodes 26a and 26b in the same pixel 25, respectively. A structure of the solid-state image sensor according to the first modified example other than the aforementioned structure is similar to the structure of the solid-state image sensor according to the foregoing embodiment.

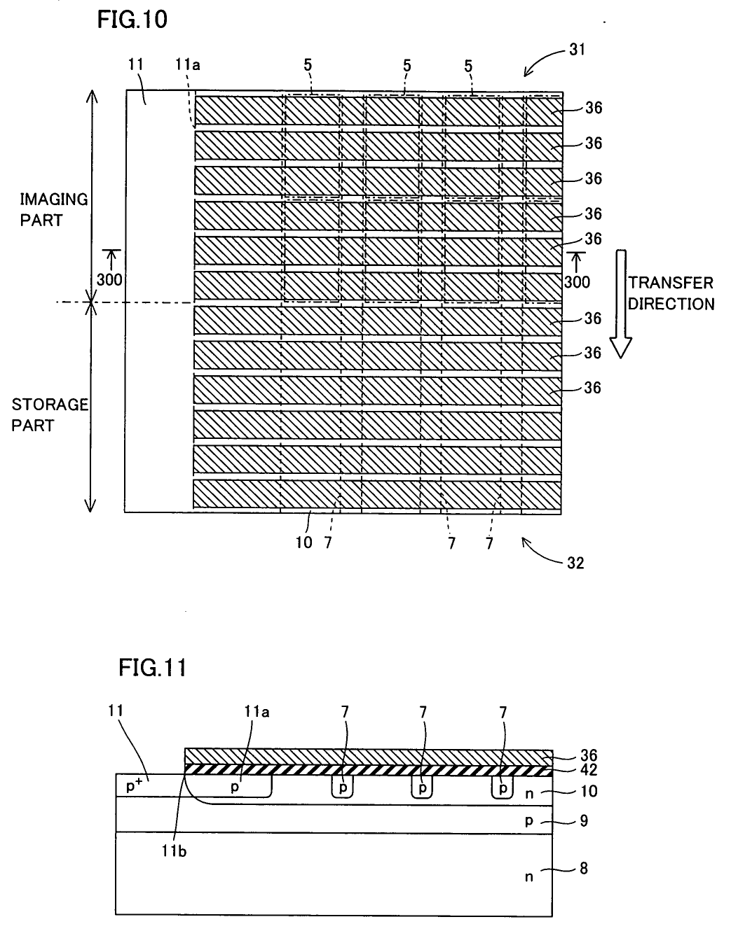

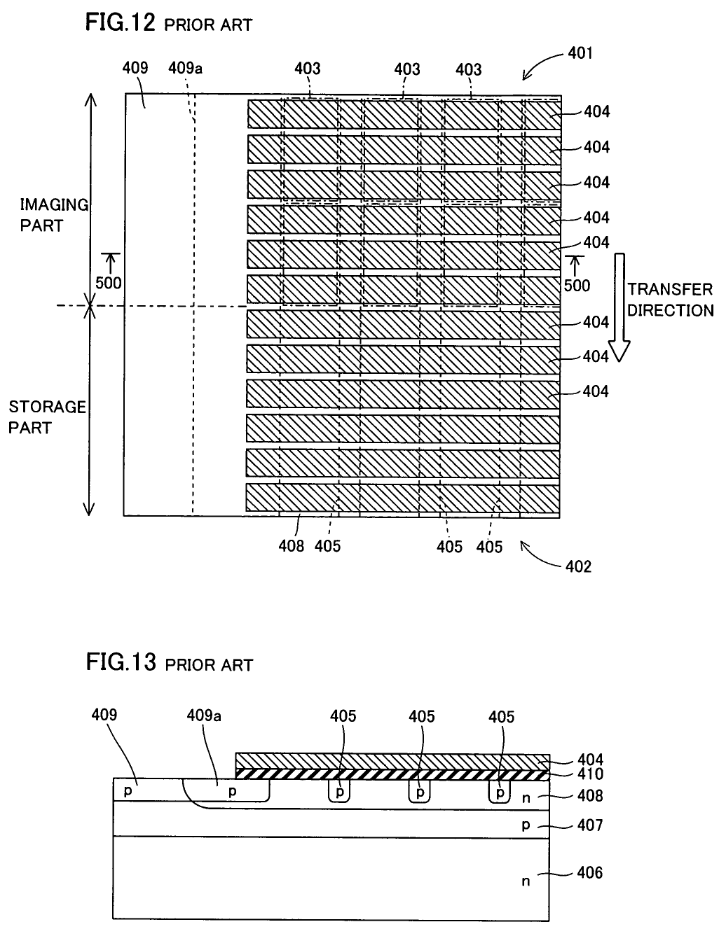

Additionally, in the foregoing embodiment, the transfer electrode is formed to overlie and extend from the n-type impurity region not only to the p-type overlap region but also to a prescribed region of the p⁺-type hole-ejection region, however, the present invention is not limited to this constitution as long as a transfer electrode is formed to overlie at least from an n-type impurity region to an edge on a p⁺-type hole ejection region side of a p-type overlap region. FIG. 10 shows a structure of an imaging part and a storage part of a solid-state image sensor according to a second modified example of the one embodiment, in which a transfer electrode is formed to overlie from an n-type impurity region to an edge on a p⁺-type hole ejection region side of a p-type overlap region. FIG. 11 shows a cross-sectional view of the solid-state image sensor according to the second modified example taken along a line 300-300 shown in FIG. 10. With reference to FIGS. 10 and 11, in the solid-state image sensor according to the second modified example, all of transfer electrodes 36 and an insulating film 42 are formed to overlie from the n-type impurity region 10 to the edge 11b on the p⁺-type hole ejection region 11 side of the p-type overlap region 11a in the imaging part 31 and the storage part 32 dissimilarly to the solid-state image sensor according the foregoing embodiment. That is, in the second modified example, the edges on the p⁺-type hole ejection region 11 side of the transfer electrodes 36 and the insulating film 42 are located at a position directly above the edge 11b on the p⁺-type hole ejection region 11 side of the p-type overlap region 11a. A structure of the solid-state image sensor according to the second modified example other than the aforementioned structure is similar to the structure of the solid-state image sensor according to the foregoing embodiment.

Furthermore, in the foregoing embodiment, all of the transfer electrodes in the imaging part and the storage part are formed to overlie and extend from the n-type impurity region not only to the p-type overlap region but also to the p⁺-type hole-ejection region, however, the present invention is not limited to this constitution. Only a transfer electrode in the vicinity of the boundary between the imaging part and the storage part may be formed to overlie and extend from the n-type impurity region not only to the p-type overlap region but also to the p⁺-type hole-ejection region.

Moreover, in the foregoing embodiment, P (phosphorus) is employed as an n-type impurity introduced to the n-type impurity region, however, the present invention is not limited to this element, an impurity other than P (phosphorus) may be employed as an n-type impurity. For example, As (arsenic) may be employed as an n-type impurity.

What is claimed is:

1. A solid-state image sensor comprising:
a first conductive type first impurity region that is formed in a main surface of a semiconductor substrate and can store electrons and holes;
a second conductive type second impurity region that is formed in the main surface of said semiconductor substrate so as to have a region where said first and second impurity regions overlap one another; and
a transfer electrode that is formed to overlie and extend at least from said first impurity region of said semiconductor substrate to the region where said first and second impurity regions overlap one another.

2. The solid-state image sensor according to claim 1, wherein said transfer electrode is formed to overlie and extend at least from said first impurity region of said semiconductor substrate to an end on said second impurity region side of the region where said first and second impurity regions overlap one another.

3. The solid-state image sensor according to claim 2, wherein said transfer electrode is formed to overlie and extend from said first impurity region of said semiconductor substrate not only to the region where said first and second impurity regions overlap one another but also to a part of a region of said second impurity region where said first and second impurity regions do not overlap one another.

4. The solid-state image sensor according to claim 1, wherein the sensor further comprises an imaging part and a storage part each of which includes said first and second impurity regions and said transfer electrode, wherein
said transfer electrode of each of said imaging part and said storage part is formed to overlie and extend at least from said first impurity region of said semiconductor substrate to the region where said first and second impurity regions overlap one another.

5. The solid-state image sensor according to claim 1, wherein said transfer electrode is formed to overlie and extend at least from said first impurity region of said semiconductor substrate to the region where said first and second impurity regions overlap one another so as to interpose a fist insulating film between the transfer electrode and the main surface of said semiconductor substrate.

6. The solid-state image sensor according to claim 1, wherein the region where said first and second impurity regions overlap one another has a second conductivity, and an impurity concentration lower than said second conductive type second impurity region.

7. The solid-state image sensor according to claim 1, wherein a plurality of said transfer electrodes are formed to extend along a direction that intersects a transfer direction of said electrons in said first impurity region and to be arranged adjacent to each other in the transfer direction of said electrons, and serve to transfer said electrons and said holes in said first impurity region by switching said transfer electrodes between ON state and OFF state, wherein
said electrons are stored in said first impurity region under said transfer electrode in ON state, and said holes are stored in said first impurity region under said transfer electrode in OFF state, wherein
said holes stored in said first impurity region under said transfer electrode in said OFF state are ejected toward said second impurity region side through the region where said first and second impurity regions overlap one another.

8. The solid-state image sensor according to claim 7, wherein said transfer electrode is turned to ON state by applying a positive voltage clock signal to said transfer electrode, and is turned to OFF state by applying a negative voltage clock signal to said transfer electrode.

9. The solid-state image sensor according to claim 1, wherein the sensor further comprises an imaging part and a storage part each of which includes said first and second impurity regions and said transfer electrode, wherein
a transfer rate of said hole in said first impurity region of said storage part is smaller than a transfer rate of said hole in said first impurity region of said imaging part, wherein
at least said transfer electrode in the vicinity of a boundary between said imaging part and said storage part is formed to overlie and extend at least from said first impurity region of said semiconductor substrate to the region where said first and second impurity regions overlap one another.

10. The solid-state image sensor according to claim 9, wherein a first clock signal is provided to said transfer electrode of said imaging part, and a second clock signal with a rate lower than said first clock signal is provided to said transfer electrode of said storage part.

11. The solid-state image sensor according to claim 9, wherein at least said transfer electrode in the vicinity of the boundary between said imaging part and said storage part is formed to overlie and extend at least from said first impurity region of said semiconductor substrate to an end on said second impurity region side of the region where said first and second impurity regions overlap one another.

12. The solid-state image sensor according to claim 11, wherein at least said transfer electrode in the vicinity of the boundary between said imaging part and said storage part is formed to overlie and extend from said first impurity region of said semiconductor substrate not only to the region where said first and second impurity regions overlap one another but also to a part of a region of said second impurity region where said first and second impurity regions do not overlap one another.

13. The solid-state image sensor according to claim 1, wherein said second impurity region, and the region where said first and second impurity regions overlap one another have a depth smaller than a depth of said first impurity region.

14. The solid-state image sensor according to claim 1, wherein the sensor further comprises a plurality of second conductive type channel stop regions that are formed in the surface of said first impurity region to be spaced at a prescribed interval from each other and to extend in the transfer direction of the electrons and holes in order to make a separation into pixels.

15. The solid-state image sensor according to claim 14, wherein said channel stop region, said second impurity region, and the region where said first and second impurity regions overlap one another have a depth smaller than a depth of said first impurity region.

16. The solid-state image sensor according to claim 14, wherein said second conductive type channel stop region has an impurity concentration lower than said second conductive type second impurity region.

17. The solid-state image sensor according to claim 1, wherein a plurality of said transfer electrodes are formed to be spaced at a prescribed interval from each other in a transfer direction of said electrons and not to overlap one another, and
each of the plurality of said transfer electrodes is formed to overlie and extend at least from said first impurity region of said semiconductor substrate to the region where said first and second impurity regions overlap one another.

18. The solid-state image sensor according to claim 1, wherein a plurality of said transfer electrodes are formed to be arranged adjacent to each other so as to overlap one another in a transfer direction of said electrons to interpose a second insulating film between said transfer electrodes, and
each of the plurality of said transfer electrodes is formed to overlie and extend at least from said first impurity region of said semiconductor substrate to the region where said first and second impurity regions overlap one another.

19. The solid-state image sensor according to claim 1, wherein said semiconductor substrate has a first conductivity, and
the sensor further comprises a second conductive type third impurity region formed in the main surface of said first conductive type semiconductor substrate, wherein
said first conductive type first impurity region is formed in a main surface of said second conductive type third impurity region.

20. A solid-state image sensor comprising:
an n-type first impurity region that is formed in a main surface of a semiconductor substrate and can store electrons and holes;
a p-type second impurity region that is formed in the main surface of said semiconductor substrate so as to have a region where said first and second impurity regions overlap one another; and
a transfer electrode that is formed to overlie and extend from said first impurity region of said semiconductor substrate not only to the region where said first and second impurity regions overlap one another but also to a part of a region of said second impurity region where said first and second impurity regions do not overlap one another.
